(19) United States
(12) Patent Application Publication
(10) Pub. No.: US 2008/0268369 A1
(43) Pub. Date: Oct. 30, 2008

(54) Organic Film Composition and Method for Forming Resist Pattern

(75) Inventors: Yoji Ikezaki, Hyogo (JP); Tatsuya Yamada, Hyogo (JP); Yoshitaka Nishijima, Hyogo (JP)

Correspondence Address: EDWARDS ANGELL PALMER & DODGE LLP, P.O. BOX 55874, BOSTON, MA, 02205, US

(73) Assignee: Nagase Chemtex Corporation, Osaka (JP)

(21) Appl. No.: 11/630,291

(22) PCT Filed: Jun. 21, 2005
(86) PCT No.: PCT/JP05/11310

§ 371 Date: Jan. 18, 2008

(30) Foreign Application Priority Data
Jun. 22, 2004 (JP) 2004-184096

(51) Int. Cl. G03C 1/00; G03F 7/20

(52) U.S. Cl. 430/270.1; 430/326

(57) ABSTRACT

Disclosed is a highly practical composition for under layers which enables to form a good undercut profile without causing a intermixing layer between an upper layer resist and an under layer film in a bi-layer photoresist process. Also disclosed is a method for forming a resist pattern. Specifically disclosed is a composition for under layer organic films for forming a resist pattern having an undercut profile on a substrate by exposing and developing a bi-layer film through a mask which bi-layer film is formed on the substrate and composed of an under layer organic film and an upper layer positive resist film. Such a composition for under layer organic films comprises an alkali-soluble resin (A) obtained by condensing a phenol component (A1) which is a mixture of 3-methylphenol and 4-methylphenol and an aldehyde component (A2) comprising an aromatic aldehyde and formaldehyde, and a solvent (B). Also specifically disclosed is a method for forming a resist pattern using such a composition of under layer organic films.

### TECHNICAL FIELD

The invention relates to an organic film composition useful for forming a resist pattern having an undercut profile on a substrate by multi-layer resist process such as bi-layer or more resist process and a method for forming a resist pattern.

### BACKGROUND ART

In recent years, a lift-off method has been widely used as one method for forming metal wiring (including wiring patterns, electrode patterns and the like) on various kinds of substrates such as a semiconductor substrate, a dielectric substrate, a pyroelectric substrate, or the like. This lift-off method is a method for forming metal wiring in a desired pattern on a substrate by forming a resist pattern on the substrate through exposure and development; forming a film of a wiring material (a metal material) on the substrate using the resist pattern as a mask by an evaporation method, a sputtering method or the like; covering the resist and the portion of the substrate where no resist film is formed with the metal film; removing the portion of the metal film on the resist pattern by dissolving the resist film under the metal film with a solvent and lifting the metal film off the substrate; and consequently leaving the metal film portion formed directly on the substrate.

In the case of forming metal wiring on the substrate by such a lift-off method, to separate the metal wiring formed directly on the substrate and the metal film formed on the resist pattern and to make separation of the unnecessary metal film on the resist pattern easy, as schematically shown in FIG. 2, it is required to carry out steps of forming a resist pattern having an undercut part (that is, the inner wall under the overhung) 24 in overhanging side face (inner wall part) 23 of an aperture region where the resist 22 is developed and removed on the surface of the substrate 21, forming the portion where no metal is deposited in the inner wall part 23, and then carrying out the lift-off process from said portion by a solvent. In this specification, the above-mentioned resist pattern inner wall profile having the undercut part is called as an undercut profile.

As a method for forming such an undercut profile is well known a method of suppressing dissolution by penetrating the upper surface of the photoresist with an aromatic solvent, particularly chlorobenzene (for example, reference to Patent Document 1). However, chlorobenzene is designated as a hazardous substance, an object for various legal restrictions, and undesirable for industrial use. Further, there is an undercut profile formation method (e.g. reference to Patent Document 2) involving forming coating in a monolayer resist having a thickness fluctuating from a hill part to a valley part of a swing curve showing the relation of the resist film thickness and the line width of the resist pattern and exposing the coating. In the case of this method, however it is difficult to form the undercut profile as desired. An undercut profile formation method using a negative-tone photoresist utilizing image reversal is also known (for example, reference to Patent Document 3). Although the negative-tone photoresist is advantageous to obtain an anti-taper profile, it is disadvantageously difficult to peel and remove the resist pattern after lift-off in this method.

The above-mentioned methods are all carried out by monolayer resist process. However, although the monolayer methods involve only a small number of steps, the process control is not so easy. From that viewpoint, bi- or multi-layer resist process as means for forming the overhung profile has been also employed to form good overhung profile with controllability. For example, as a method for forming the undercut profile by the multilayer resist method is well known a method using PMGI (polydimethylglutarimide) for a resin for an under layer and novolak-based photoresist for an upper layer (for example, reference to Patent Document 4). However, the method requires baking conditions at a temperature as high as 160° C. or higher in the under layer film formation step. Employment of such a high baking temperature in the photolithographic process in fabrication of semiconductor integrated circuits or light emitting devices with a high integration degree is not so common and it is required to install a facility sufficient to deal with baking at such a high temperature for PMGI type.

On the other hand, if a composition containing a novolak resin is intended to be also applied for the under layer, inter-mixing occurs in the boundary between the upper layer photoresist and the under layer resist and consequently, there occur the following undesirable problems: (1) the film thickness differs depending on the positions in the plane of the substrate; (2) the side face profile of the resist pattern differs depending on the positions of the substrate; and (3) no undercut profile is formed in some positions of the plane of the substrate. Therefore, materials of an upper layer composition and an under layer composition for which solvents for dissolution differ with each other have been proposed (for example, reference to Patent Document 5). However, there is a disadvantage that in the case of using such materials, coating apparatus exclusive for the respective materials has to be made available for separating waste liquids. Further, there is a method for forming resist patterns by limiting the drying time of the film formation of the upper layer and the under layer (for example, reference to Patent Document 6), however this method is originally a technique of aiming formation of a regular taper shape and is insufficient as means for preventing inter-mixing between the upper layer and the under layer. As described, no composition for an under layer capable of avoiding inter-mixing with no need of high temperature baking has been made available.

### Patent Document 1: Japanese Patent Application Laid-Open (JP-A) No. 8-124848

### Patent Document 2: JP-A No. 2000-162783

### Patent Document 3: JP-A No. 6-27654

### Patent Document 4: JP-A No. 02-17643

### Patent Document 5: JP-A No. 11-20441

### Patent Document 6: JP-A No. 2002-231603

### DISCLOSURE OF THE INVENTION

### Problems to be Solved by the Invention

In view of the above state of the art, it is an object of the invention to provide an organic film composition for an under layer and a resist pattern formation method which are practically highly usable and capable of forming a good undercut profile without formation of an inter-mixing layer between an upper layer photoresist and the organic under layer and applicable for multi-layer resist process to be easily carried out by conventional facilities for a monolayer resist process with no need of an additional facility for a high baking temperature in the process of fabricating semiconductor integrated circuits and light emitting devices.

### Means for Solving the Problems

The inventors of the invention have made intensive investigations to solve the above-mentioned problems and have found that use of a specified alkali-soluble resin as an under layer organic film composition accomplishes the above-mentioned purpose, leading to completion of the invention. That is, the invention provides an organic film composition for an under layer organic film for forming a resist pattern with an undercut profile on a substrate by carrying out exposure through a mask and development of a bilayer organic film composed of the under layer organic film and an upper layer positive photoresist film formed on the substrate, wherein the composition comprises (A) an alkali-soluble resin obtained by condensation of (A1) a phenol component which is a mixture of 3-methylphenol and 4-methylphenol and (A2) an aldehyde component comprising an aromatic aldehyde and formaldehyde, and (B) a solvent.

The invention also provides a method for forming a resist pattern comprising steps of applying the organic film composition according to any one of claims 1 to 6 to a substrate; baking the composition at a temperature equal to or lower than 130° C. for forming an under layer film; applying the positive-tone photoresist composition to the under layer film and baking the photoresist composition for forming an upper layer positive-tone photoresist film; and carrying out exposure through a mask and development for forming a resist pattern having an undercut profile on the substrate.

### EFFECTS OF THE INVENTION

With above-mentioned configuration of the invention, no inter-mixing is caused in the boundary of the upper layer and the under layer even if the under layer organic film composition contains a novolak resin and a solvent same as those used in the upper layer.

With the above-mentioned configuration of the invention, without being accompanied with such undesirable problems as: (1) the film thickness differs depending on the positions in the plane of the substrate; (2) the side face profile of the resist pattern differs depending on the positions of the substrate; and (3) no undercut profile is formed in some positions of the plane of the substrate, a good overhung profile can be easily formed.

With the above-mentioned configuration of the invention, the resist film can be fired at a temperature of 130° C. or lower and with no need of a facility usable for dealing with the baking temperature as high as the temperature for baking PMGI type, the inventions can be carried out using facilities same as those for monolayer resist process.

### BRIEF DESCRIPTION OF THE DRAWINGS

FIG. 1 is a schematic cross-sectional illustration of a resist pattern with an undercut profile formed by a resist pattern formation method of the invention.

FIG. 2 is a schematic cross-sectional illustration of a conventional resist pattern with an undercut profile.

FIG. 3 is a schematic process of pattern formation of the invention.

### EXPLANATION OF SYMBOLS

11, 21, 31: substrate
12, 33: upper layer photoresist film
13, 23: overhung
14, 32: under layer organic film
22: photoresist film
24: undercut
34: exposure part
35: photomask light shielding pattern

### BEST MODES FOR CARRYING OUT THE INVENTION

An organic film composition of the invention is an under layer organic film composition for forming a resist pattern having an undercut profile on a substrate by exposing a bilayered organic film of an under layer organic film and an upper layer positive-tone photoresist film formed on the substrate through a mask and developing the film. Examples of the above-mentioned substrate to be used include various kinds of substrate such as a semiconductor substrate, a dielectric substrate, and a pyroelectric substrate. The composition of the invention is an organic film composition to be used for so-called lift-off process. Conventional multi-layer lift-off process typically involves applying a PMGI under-layer on a substrate, baking the layer at a high temperature, applying an upper layer photoresist (positive-tone or negative-tone) thereon, and baking the photoresist for forming a resist film; exposing the resist film through a mask, and successively either developing the resist of both upper and under layers or developing the upper layer resist film, carrying out secondary exposure using the remaining upper layer resist film as a mask, and developing the under layer resist film for forming a resist pattern with an undercut profile (resist pattern formation process); and depositing a metal film on the entire substrate by evaporation and removing an unnecessary part of the metal film together with the resist film for forming a metal film pattern (lift-off process). If necessary, these processes may be repeated to form a multi-layer metal film pattern. The under layer organic film composition of the invention is advantageous in the capability for forming a resist pattern with a desirable undercut profile by process involving a low temperature baking and one-time exposure in place of the resist pattern formation process with the undercut profile by the above-mentioned conventional multi-layer resist process. The organic film composition of the invention involves an organic film composition (a resist composition) containing a photosensitizer and an organic film composition containing no photosensitizer.

The alkali-soluble resin (A) of the organic film composition of the invention is obtained by condensation of (A1) a phenol component which is a mixture of 3-methylphenol and 4-methylphenol and (A2) an aldehyde component comprising an aromatic aldehyde and formaldehyde. The mixing ratio (ratio by weight) of 3-methylphenol and 4-methylphenol with respect to the phenol component (A1) is in a range preferably from (95:5) to (5:95) and more preferably from (70:30) to (30:70) from the viewpoint of the thickness of resist film formed after development.

The above-mentioned aldehyde component (A2) comprises an aromatic aldehyde and formaldehyde. In this connection, as the above-mentioned formaldehyde not only means formaldehyde itself but also a precursor thereof can be used in place of or together with formaldehyde in the invention and such configuration is also within scope of the invention. The precursor of formaldehyde means compounds which give formaldehyde in a reaction solution. Examples of the above-mentioned aromatic aldehyde include salicylaldehyde, benzaldehyde, 3-hydroxybenzaldehyde, 4-hydroxybenzaldehyde, and terephthalaldehyde and they may be used alone or two or more of them may be used in combination. Among them are salicylaldehyde and benzaldehyde preferable. In the case where an aromatic aldehyde and formaldehyde are used in combination, the mixing ratio by weight of the aromatic aldehyde and formaldehyde is in a range preferably from (70:30) to (5:95) and more preferably from (60:40) to (15:85). The above-mentioned precursor of formaldehyde may include, for example, butylhemiformal, paraformaldehyde, and trioxane.

Condensation of the above-mentioned phenol component (A1) and aldehyde component (A2) can be carried out by a normal method and for example, the condensation may be carried out by reaction of both components in bulk or in a solvent. At that time, as a catalyst may be used an organic acid (e.g., formic acid, oxalic acid, p-toluenesulfonic acid, trichloroacetic acid, or the like), an inorganic acid (e.g., phosphoric acid, hydrochloric acid, sulfuric acid, perchloric acid, or the like), and a divalent metal salt (zinc acetate, magnesium acetate, or the like). In that case, the loading ratio of the above-mentioned phenol component (A1) and aldehyde component (A2) is generally in a range from (60:80) to (40:20).

The above-mentioned alkali-soluble resin (A) is preferable to have a weight average molecular weight of 4000 to 14000 on the basis of polystyrene standards. It is more preferably 5000 to 13000. The weight average molecular weight can be measured by gel permeation chromatography.

As the above-mentioned alkali-soluble resin (A) may be used the obtained polycondensate as it is or after the oligomer components are fractionated and removed by several kinds of solvents with different solubility of resins by a conventional method.

The above-mentioned alkali-soluble resin (A) is a novolak resin and insoluble in water and soluble in an aqueous alkaline solution. Accordingly, it can be subjected to development treatment with an aqueous alkaline solution such as an aqueous tetramethylammonium hydroxide solution.

The solvent (B) in the organic film composition of the invention may be, for example, ketones such as 2-heptanone, methyl cellosolve, ethyl cellosolve, butyl cellosolve, methyl cellosolve acetate, ethyl cellosolve acetate, methoxymethyl propionate, methyl diglyme, methyl isobutyl ketone, methyl amyl ketone, cyclohexanone, dimethylformamide, N-methylpyrrolidone, acetone, methyl ethyl ketone, and 1,1,1-trimethylacetone; polyhydric alcohols and their derivatives such as ethylene glycol monoacetate, propylene glycol monoacetate, and monomethyl ether, monoethyl ether, monopropyl ether, monobutyl ether, or monophenyl ether of diethylene glycol or diethylene glycol monoacetate; cyclic ethers such as dioxane; and esters such as ethyl lactate (EL), methyl acetate, ethyl acetate, butyl acetate, methyl propionate, ethyl pyruvate, methyl 3-methoxypropionate, and methyl 3-ethoxypropionate. These solvents may be used alone or two or more of them may be used in combination. Glycol ether esters such as propylene glycol and monomethyl ether acetate are preferable among them.

In that case, the solvent (B) is preferable to be the same as a solvent contained in an upper layer photoresist resin composition, which will be described later.

In the organic film composition of the invention, the addition ratio of the solvent (B) is not particularly limited if it is possible to form a coating film uniform and free from pinholes and application unevenness on a substrate. Generally, it is preferably in a range from 100 to 500 parts by weight and more preferably in a range from 130 to 300 parts by weight to 100 parts by weight of the above-mentioned alkali-soluble resin (A).

A production method of the organic film composition of the invention is not particularly limited and the above-mentioned alkali-soluble resin (A) and components to be added based on the necessity, which will be described later, may be dissolved in the above-mentioned solvent (B) to obtain an even solution.

The organic film composition of the invention may be a radiation sensitive composition obtained by adding a naphthoquinone diazide compound. Examples of the naphthoquinone diazide compound include completely esterified compounds or partially esterified compounds of polyhydroxybenzophenones such as 2,3,4-trihydroxybenzophenone and 2,3,4,4′-tetrahydroxybenzophenone with naphthoquinone-1,2-diazido-5-sulfonic acid or naphthoquinone-1,2-diazido-4-sulfonic acid. The naphthoquinonediazide compounds may also include compounds defined by the following general formula (I).

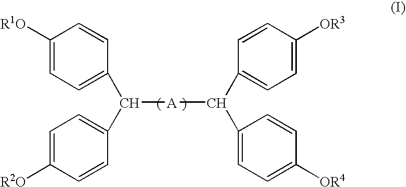

In the formula, R¹, R², R³, and R⁴ may be same or different and independently denote a hydrogen atom or a group defined by the following formula. At least one of R¹, R², R³, and R⁴ is a group defined by the following formula.

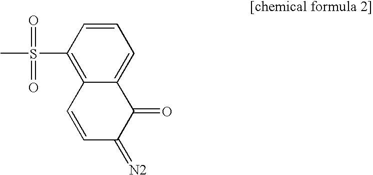

In the general formula (I), A denotes a phenylene group, an optionally branched C₁ to C₁₂ alkylene group, an optionally substituted arylene group, or a heteroarylene group.

In the general formula (I), A preferably denotes a phenylene group such as an o-phenylene, m-phenylene, or p-phenylene group; an alkylene group such as ethylene, trimethylene, tetramethylene, or propylene; an arylene or heteroarylene group such as an anthracenylene, thienylene, terphenylene, pyrenylene, terthienylene, or perylenylene group. Among them, p-phenylene group is preferable. The heteroarylene group is a divalent group derived from a hetero atom-containing aromatic heterocyclic compound.

Examples may also include another quinonediazido group-containing compounds such as o-benzoquinone diazide, o-naphthoquinonediazide, o-anthraquinone diazide or o-naphthoquinonediazide sulfonic acid ester or its nuclear-substituted derivative, and further a reaction product of o-naphthoquinonesulfonyl chloride with a compound having a hydroxyl group or an amino group such as phenol, p-methoxyphenol, dimethylphenol, hydroquinone, bisphenol A, naphthol, carbinol, pyrocatechol, pyrogallol, pyrogallol monomethyl ether, pyrogallol 1,3-dimethyl ether, gallic acid, partially esterified or etherified gallic acid remaining some hydroxyl groups, aniline, or p-aminodiphenylamine. These compounds may be used alone or two or more of them may be used in combination.

In general, these naphthoquinone diazide compounds are produced typically, for example, by carrying out condensation and complete or partial esterification of the above-mentioned polyhydroxybenzophenone with naphthoquinone-1,2-dioazido-5-sulfonyl chloride or naphthoquinone-1,2-diazido-4-sulfonyl chloride in a proper solvent such as dioxane in the presence of an alkali such as triethanolamine, an alkali carbonate or an alkali hydrogen carbonate.

Unless the aim of the invention is inhibited, the organic film composition of the invention may contain, for example, a resin for improving the properties of a resist film, an alkali-soluble resin other than the above-mentioned resin (A), a plasticizer, a stabilizer, a surfactant, an adhesion assisting agent, a dye for improving visibility of the resist pattern after development, and a sensitizer for improving the sensitizing effect.

A method for forming a resist pattern of the invention involves at first forming an under layer organic film by applying the above-mentioned organic film composition on a substrate and baking the composition at a temperature of 130° C. or lower; forming an upper layer positive-tone photoresist film by applying a positive-tone photoresist composition on the under layer organic film and baking the composition; and then forming a resist pattern having an undercut profile on the substrate by carrying out exposure through a mask and development of these films.

The above-mentioned positive-tone photoresist composition is not particularly limited and those obtained by dissolving an alkali-soluble novolak-based resin and a photosensitizer in a solvent may be used. Practically, the alkali-soluble novolak resin may include reaction products of phenols and aldehydes. Examples of the phenols include aromatic hydroxy compounds such as phenol, o-, m- or p-cresol, 2,5-xylenol, 3,6-xylenol, 3,4-xylenol, 2,3,5-trimethylphenol, 4-tert-butylphenol, 2-tert-butylphenol, 3-tert-butylphenol, 2-ethylphenol, 3-ethylphenol, 4-ethylphenol, 3-methyl-6-tert-butylphenol, 4-methyl-2-tert-butylphenol, 2-naphthol, 1,3-dihydroxynaphthalene, 1,6-dihydroxynaphthalene, and 1,7-dihydroxynaphthalene. Examples of aldehydes are formaldehyde, para-formaldehyde, acetaldehyde, propyl aldehyde, benzaldehyde, and phenyl aldehyde.

Examples of the above-mentioned photosensitizer may be those exemplified above-mentioned.

Examples of the solvent may be those exemplified above-mentioned.

Examples usable as the above-mentioned positive-tone photoresist composition may also be compositions described in JP-A Nos. 6-130662, 6-51506, and 2000-171968.

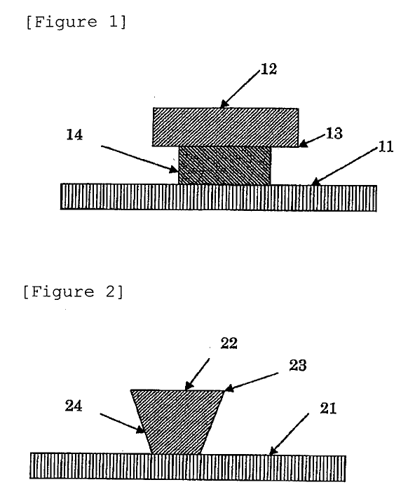

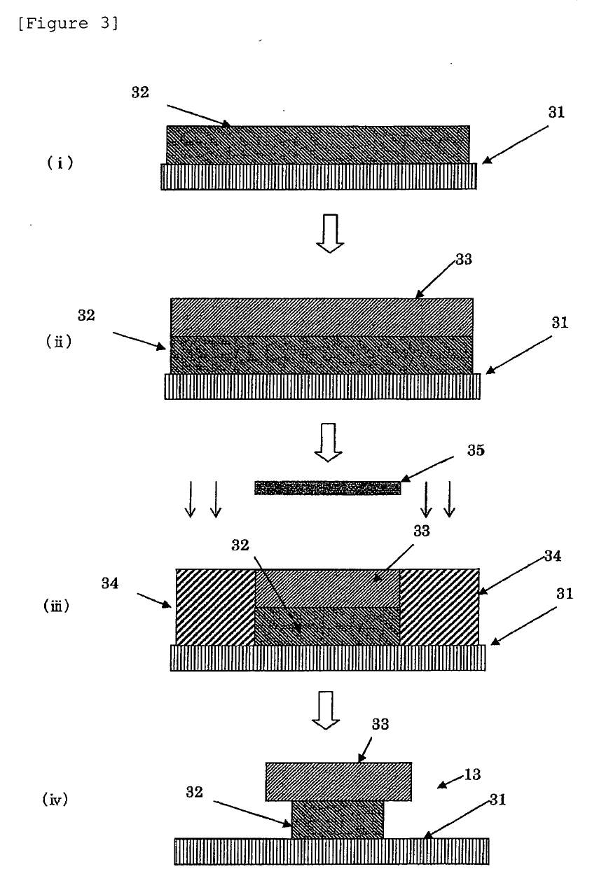

As shown in FIG. 3, a method for forming a resist pattern of the invention typically involves, for example, steps of (i) forming an under organic film layer; (ii) an upper resist film layer; (iii) exposing the bilayer film; and (iv) developing the bilayer film. Hereinafter, the method will be described in detail. At first, the above-mentioned organic film composition of the invention (containing a photosensitizer or no photosensitizer) is applied to a substrate by a spinner or the like and dried or fired at a temperature equal to or lower than 130° C., preferably in a range from 80 to 125° C., and more preferably in a range from 100 to 120° C. for preferably 30 to 300 seconds and more preferably 60 to 240 seconds to form the under organic film layer (the step (i)). The above-mentioned positive-tone photoresist solution containing respective components is applied thereto by a spinner or the like and dried or fired at a temperature equal to or lower than 130° C., preferably in a range from 80 to 125° C., and more preferably in a range from 90 to 120° C. for preferably 30 to 300 seconds and more preferably 60 to 240 seconds to form the upper resist film layer (the step (ii)). The layers are exposed through a mask pattern by ultraviolet rays (preferably i-ray) using a low pressure mercury lamp, a high pressure mercury lamp, an ultrahigh pressure mercury lamp, an arc lamp, a xenon lamp or the like (the step (iii)). Next, if necessary, baking or drying may be carried out again at a low temperature preferably in a range from 80 to 125° C. and more preferably in a range from about 100 to 120° C. for preferably 30 to 240 seconds and more preferably 60 to 180 seconds. Next, the resulting substrate is immersed in a developer solution, for example, an aqueous alkaline solution such as an aqueous solution containing 1 to 10% by weight of tetramethylammonium hydroxide, then the exposed parts of the upper resist film layer and the under organic film layer can be selectively and collectively dissolved and removed to form the resist pattern with an undercut profile on the substrate (the step (iv)). FIG. 1 schematically shows the undercut profile of the resist pattern to be formed by the method of the invention. The resist pattern in which the upper photoresist film layer 12 and the under organic film layer 14 form the overhung 13 and which thus has the undercut part, that is, the inner wall part below the overhung, is formed on a surface of the substrate 11.

Using the resist pattern obtained in the above-mentioned manner and, if necessary, rinsed with ultrapure water and dried as a mask, a metal film is deposited by a conventionally known method such as vacuum evaporation or sputtering, and together with the metal film, the resist pattern is removed by a resist stripper solution (lift-off step) to form a circuit pattern on the substrate. Further, if necessary, the above-mentioned resist pattern formation step and the lift-off step may be repeated to form a multilayer metal film pattern.

Hereinafter, the invention will be described more in detail along with Examples, however it is not intended that the invention be limited to the illustrated Examples.

### SYNTHESIS EXAMPLE 1

### Synthesis of Novolak Resin (a-1)

As shown in Table 1, a cresol-novolak-based resin (a-1) was obtained by reaction of a mixture of 3-methylphenol and 4-methylphenol at a ratio by weight of 50:50 and a mixture of salicylaldehyde and benzaldehyde at 100° C. for 120 minutes using oxalic acid as a catalyst in a conventional manner. The weight average molecular weight (Mw) of the resin measured by gel permeation chromatography was 9500.

### SYNTHESIS EXAMPLES 2 To 14

### Synthesis of Novolak Resins (a-2) to (a-14)

Prescribed weights of the monomers and aldehydes shown in Table 1 were loaded and polymerization was carried out in the same manner as that in Synthesis Example 1 to obtain novolak resins (a-2) to (a-14).

### SYNTHESIS EXAMPLE 15

A cresol-novolak-based resin (a-15′) was obtained in the same manner as that in Synthesis Example 1, except the reaction time was changed to 100 minutes. The weight average molecular weight (Mw) of the resin measured by gel permeation chromatography was 7200 and the content of the un-reacted monomers based on the surface area ratio was 6.1%. After 100 g of the obtained cresol-novolak-based resin (a-15′) was dissolved in 220 g of ethyl acetate at 23° C., 220 g of n-hexane was added in a stirring condition. After addition of n-hexane, the mixture was stirred further for 30 minutes and kept still for 1 hour. After the upper layer was removed by decantation, the remaining resin layer was heated at 70° C. under reduced pressure (8 to 10 mmHg) to remove the solvent and obtain 80 g of novolak resin (a-15). The weight average molecular weight (Mw) of the novolak resin (a-15) measured by gel permeation chromatography was 9900 and the content of the monomer by surface area ratio was 0.7%.

TABLE 1

| | | | | | | Weight average |
|---|---|---|---|---|---|---|
| | | | | | | molecular weight |
| | | | | | | on the basis of |
| Novolak | Monomer loading ratio (ratio by weight) | | | Aldehyde loading ratio (ratio by weight) | | polystyrene |
| resin | Methylphenol A | Methylphenol B | Methylphenol C | Aldehyde 1 | Aldehyde 2 | standards |
| a-1 | 3-methylphenol | 4-methylphenol | — | Formaldehyde | Salicylaldehyde | 9500 |
| | 50 | 50 | | 70 | 30 | |
| a-2 | 3-methylphenol | 4-methylphenol | — | Formaldehyde | Salicylaldehyde | 5000 |
| | 50 | 50 | | 65 | 35 | |
| a-3 | 3-methylphenol | 4-methylphenol | — | Formaldehyde | Salicylaldehyde | 7000 |
| | 50 | 50 | | 50 | 50 | |
| a-4 | 3-methylphenol | 4-methylphenol | — | Formaldehyde | Benzaldehyde | 6500 |
| | 50 | 50 | | 70 | 30 | |
| a-5 | 3-methylphenol | 4-methylphenol | 2,3,5-trimethylphenol | Formaldehyde | — | 2100 |
| | 35 | 40 | 25 | 100 | | |
| a-6 | 3-methylphenol | 4-methylphenol | 2,3,5-trimethylphenol | Formaldehyde | — | 2800 |
| | 35 | 40 | 25 | 100 | | |
| a-7 | 3-methylphenol | 4-methylphenol | 2,3,5-trimethylphenol | Formaldehyde | — | 3300 |
| | 35 | 40 | 25 | 100 | | |
| a-8 | 3-methylphenol | 4-methylphenol | 3,5-xylenol | Formaldehyde | — | 12510 |
| | 60 | 30 | 10 | 100 | | |
| a-9 | 3-methylphenol | 4-methylphenol | 3,5-xylenol | Formaldehyde | — | 9400 |
| | 60 | 30 | 10 | 100 | | |
| a-10 | 3-methylphenol | 4-methylphenol | 3,5-xylenol | Formaldehyde | — | 4400 |
| | 47 | 23 | 30 | 100 | | |
| a-11 | 3-methylphenol | — | — | Formaldehyde | Salicylaldehyde | 2000 |
| | 100 | | | 70 | 30 | |
| a-12 | 3-methylphenol | 4-methylphenol | — | Formaldehyde | — | 2000 |
| | 40 | 60 | | 100 | | |
| a-13 | 3-methylphenol | 4-methylphenol | — | Formaldehyde | — | 6400 |
| | 60 | 40 | | 100 | | |
| a-14 | 3-methylphenol | 4-methylphenol | — | Formaldehyde | — | 12000 |
| | 60 | 40 | | 100 | | |
| a-15 | 3-methylphenol | 4-methylphenol | — | Formaldehyde | Salicylaldehyde | 9900 (after |
| | 50 | 50 | | 70 | 30 | fractionation) |

### EXAMPLE A1

After 100 g of novolak resin (a-1) was dissolved in 340 g of propylene glycol monomethyl ether acetate to obtain an even solution, the solution was filtered with a microfilter having a hole diameter of 0.2 μm to prepare an under layer organic film composition (Lw-R1).

### <Evaluation of Intermixing>

Intermixing with the upper layer resist was evaluated as follows. That is, after the under layer organic film composition (Lw-R1) was applied to a silicon substrate by a spinner in a manner that the film thickness was to be 2.0 μm, the composition was baked at 100° C. for 2 minutes on a hot plate. After that, the initial film thickness (X) was measured. Successively, after 5 mL of propylene glycol monomethyl ether acetate, which was the same solvent as the solvent contained in the under layer organic film composition (Lw-R1), was dropwise applied to the substrate coated with the under layer organic film composition, the substrate was kept still for 3 seconds and the solvent was removed by a spinner. After that, the substrate was baked at 120° C. for 2 minutes and the film thickness (Y) was measured.

The film remaining ratio was calculated based on the following calculation expression. The result was shown in Table 2.

Film remaining ratio (%)=(Y/X)×100

If the film remaining ratio was higher than 90% and not higher than 100%, it was determined to be qualified.

### EXAMPLES A2 TO A11 AND COMPARATIVE EXAMPLES A1 TO A10

Under layer organic film compositions (Lw-R2) to (Lw-R21) were prepared using novolak resins (a-2) to (a-15) and 5 mL of the solvent same as that contained in each under layer organic film composition was dropwise applied in the same manner and the film remaining ratio was evaluated. The under layer organic film compositions and results were shown in Table 2.

The abbreviations in Table 2 are as follows.

PMA: propylene glycol monomethyl ether acetate
EEP: 3-ethoxyethyl propionate
EL: ethyl lactate
MAK: 2-heptanone

TABLE 2

| | Under layer | Novolak resin | | Solvent | | Evaluation result |
|---|---|---|---|---|---|---|
| | organic film | | Addition | | Addition | film remaining |
| | composition | Type | amount | Type | amount | ratio (%) |
| Example A1 | Lw-R1 | a-1 | 100 | PMA | 340 | 97 |
| Example A2 | Lw-R2 | a-1 | 100 | EL | 340 | 91 |
| Example A3 | Lw-R3 | a-1 | 100 | EEP | 340 | 91 |
| Example A4 | Lw-R4 | a-1 | 100 | MAK | 340 | 91 |
| Example A5 | Lw-R5 | a-1 | 100 | Cyclohexanone | 340 | 92 |
| Example A6 | Lw-R6 | a-2 | 100 | PMA | 340 | 95 |
| Example A7 | Lw-R7 | a-3 | 100 | PMA | 340 | 96 |
| Example A8 | Lw-R8 | a-1 | 100 | PMA | 170 | 93 |
| | | | | EEP | 170 | |
| Example A9 | Lw-R9 | a-15 | 100 | PMA | 340 | 97 |
| Example A10 | Lw-R10 | a-15 | 96 | PMA | 340 | 91 |
| | | a-12 | 4 | | | |
| Example A11 | Lw-R11 | a-4 | 100 | PMA | 340 | 92 |
| Comparative | Lw-R12 | a-5 | 100 | PMA | 340 | 0 |
| Example A1 | | | | | | |
| Comparative | Lw-R13 | a-6 | 100 | PMA | 340 | 1 |
| Example A2 | | | | | | |
| Comparative | Lw-R14 | a-7 | 100 | PMA | 340 | 1 |
| Example A3 | | | | | | |
| Comparative | Lw-R15 | a-8 | 100 | PMA | 340 | 28 |
| Example A4 | | | | | | |
| Comparative | Lw-R16 | a-9 | 100 | PMA | 340 | 17 |
| Example A5 | | | | | | |
| Comparative | Lw-R17 | a-10 | 100 | PMA | 340 | 2 |
| Example A6 | | | | | | |
| Comparative | Lw-R18 | a-11 | 100 | PMA | 340 | 2 |
| Example A7 | | | | | | |
| Comparative | Lw-R19 | a-12 | 100 | PMA | 340 | 13 |
| Example A8 | | | | | | |
| Comparative | Lw-R20 | a-13 | 100 | PMA | 340 | 25 |
| Example A9 | | | | | | |
| Comparative | Lw-R21 | a-14 | 100 | PMA | 340 | 35 |
| Example A10 | | | | | | |

### <Synthesis of Naphthoquinonediazide Compound Type Photosensitizer>

### SYNTHESIS EXAMPLE 16

### Synthesis of Photosensitizer (b-1)

The compound defined by the following formula (II) was used as a polyhydroxy compound, and 1,2-naphthoquinonediazido-5-sulfonic acid chloride in an amount equivalent to 75 mol % of the hydroxyl groups of the compound was dissolved in dioxane to obtain 10% solution. While the solution is controlled at a temperature of 20 to 25° C., triethylamine in an amount 1.2 times as much as the equivalent of 1,2-naphthoquinonediazido-5-sulfonic acid chloride was dropwise added for 30 minutes and reaction of the mixture was kept continuing further for 2 hours for completion. The reaction mixture was added to 1% aqueous hydrochloric acid solution and the precipitated solid matter was filtered and washed with ion-exchanged water and dried to obtain naphthoquinonediazide photosensitizer (b-1).

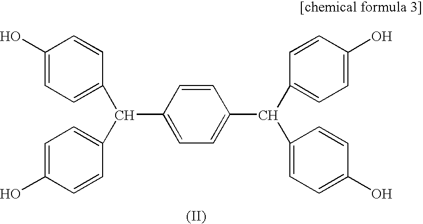

### SYNTHESIS EXAMPLE 17

### Synthesis of Photosensitizer (b-2)

The compound defined by the following formula (III) was used as a polyhydroxy compound, and 1,2-naphthoquinonediazido-5-sulfonic acid chloride in an amount equivalent to 75 mol % of the hydroxyl groups of the compound was dissolved in dioxane to obtain 10% solution. While the solution is controlled at a temperature of 20 to 25° C., triethylamine in an amount 1.2 times as much as the equivalent of 1,2-naphthoquinonediazido-5-sulfonic acid chloride was dropwise added for 30 minutes and reaction of the mixture was kept continuing further for 2 hours for completion. The reaction mixture was added to 1% aqueous hydrochloric acid solution and the precipitated solid matter was filtered and washed with ion-exchanged water and dried to obtain naphthoquinonediazide photosensitizer (b-2).

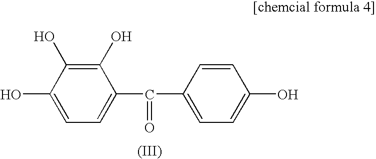

### <Preparation of Positive-Tone Resist Composition for Upper Layer>

### PREPARATION EXAMPLES 1 TO 9

After 100 parts by weight of the novolak resin (a-13), 16 parts by weight of naphthoquinonediazide compound (b-1), and 240 parts by weight of propylene glycol monomethyl ether acetate were mixed to obtain a uniform solution, the solution was filtered by a microfilter with a hole diameter of 0.2 μm to prepare a positive-tone resist composition for an upper layer (UP-PR1).

In the same manner, positive-tone resist compositions for upper layers (UP-PR2) to (UP-PR9) were prepared by mixing the components at the mixing ratio (part by weight) as shown in Table 3.

The abbreviations in Table 3 are as follows.

PMA: propylene glycol monomethyl ether acetate
EEP: 3-ethoxyethyl propionate
EL: ethyl lactate
MAK: 2-heptanone

TABLE 3
Positive-
tone resist

| composition | Novolak resin | | Photosensitizer | | Solvent | |
|---|---|---|---|---|---|---|
| for upper | | Addition | | Addition | | Addition |
| layer | Type | amount | Type | amount | Type | amount |
| UP-PR1 | a-13 | 100.0 | b-1 | 16.0 | PMA | 240.0 |
| UP-PR2 | a-13 | 100.0 | b-2 | 16.0 | PMA | 240.0 |
| UP-PR3 | a-14 | 100.0 | b-1 | 16.0 | PMA | 240.0 |
| UP-PR4 | a-14 | 100.0 | b-2 | 16.0 | PMA | 240.0 |
| UP-PR5 | a-13 | 100.0 | b-1 | 16.0 | EL | 240.0 |
| UP-PR6 | a-13 | 100.0 | b-1 | 16.0 | EEP | 240.0 |
| UP-PR7 | a-13 | 100.0 | b-1 | 16.0 | MAK | 240.0 |
| UP-PR8 | a-13 | 100.0 | b-1 | 16.0 | Cyclo- | 240.0 |
| | | | | | hexa- | |
| | | | | | none | |
| UP-PR9 | a-13 | 100.0 | b-1 | 16.0 | PMA | 120.0 |
| | | | | | EEP | 120.0 |

### EXAMPLES B1 TO B15 AND COMPARATIVE EXAMPLES B1 TO B10

The under layer organic film composition (Lw-R1) was applied to a silicon substrate with a diameter of 125 mm by a spinner and dried at 120° C. for 120 seconds with a hot plate to form an under layer film with a thickness of 1.0 μm. The positive-tone resist composition for an upper layer (UP-PR1) was applied to the substrate coated with the under layer organic film by a spinner and dried at 120° C. for 120 seconds with a hot plate to form an upper layer film with a thickness of 2 μm.

### <Bilayer Resist Pattern Formation Evaluation (1)>

The thickness of the resist film at the center (C) of the substrate and the thickness of the resist film at any optional point (D) 2 cm from the edge of the substrate were measured by an optical film thickness measurement instrument. The results (C and D) of the thickness measurement of the resist film before exposure were evaluated based on the following standard.

E=(C/D)×100

◯: 90≦E≦100 (free from intermixing or an intermixing layer was so extremely thin as compared with the bilayer resist film thickness that the layer could be negligible in terms of the profile).
x: 0<E<90 (there was an intermixing layer and the profile is determined to be considerably different in the plane of the substrate and the upper resist dropping trace was observable with eyes).

After being subjected to exposure using an i-ray stepper (LD5010i, manufactured by Hitachi, Ltd.), the substrate was fired at 110° C. for 60 seconds. The exposed substrate was subjected to development with an aqueous solution containing 2.38% of tetramethylammonium hydroxide at 23° C. for 150 seconds by DIP method and rinsed with ultrapure water for 20 seconds and dried. The line and space resist pattern with line width of 5 μm in the center part (E) of the thus obtained silicon substrate and the line and space resist pattern at any optional point (F) 2 cm from the edge of the substrate were observed by a scanning electron microscope.

The cross-sectional profile was evaluated based on the following standard.

◯: Both of E and F had a profile having the same cross-section of the pattern.
Δ: Although the both cross-sectional profiles at E and F points were undercut profiles, the profiles were not same.
x: Intermixing was significant, and no undercut profile was observed at E point.

The positive resist compositions for an upper layer (UP-PR2) to (UP-PR9) and under layer organic film compositions (Lw-R1) to (Lw-R21) were used and evaluation was carried out in the same manner. The results are shown in Table 4.

TABLE 4

| | | | Evaluation | |
|---|---|---|---|---|
| | | | result of film | |
| | Upper | Under layer | thickness | |
| | layer | organic film | measurement | Cross-sectional |
| | resist | composition | (E/%) | profile |
| Example B1 | UP-PR1 | Lw-R1 | ∘ | ∘ |
| Example B2 | UP-PR2 | Lw-R7 | ∘ | ∘ |
| Example B3 | UP-PR6 | Lw-R3 | ∘ | ∘ |
| Example B4 | UP-PR4 | Lw-R1 | ∘ | ∘ |
| Example B5 | UP-PR5 | Lw-R2 | ∘ | ∘ |
| Example B6 | UP-PR7 | Lw-R4 | ∘ | ∘ |
| Example B7 | UP-PR8 | Lw-R5 | ∘ | ∘ |
| Example B8 | UP-PR1 | Lw-R6 | ∘ | ∘ |
| Example B9 | UP-PR1 | Lw-R7 | ∘ | ∘ |
| Example B10 | UP-PR9 | Lw-R8 | ∘ | ∘ |
| Example B11 | UP-PR9 | Lw-R1 | ∘ | ∘ |
| Example B12 | UP-PR3 | Lw-R8 | ∘ | ∘ |
| Example B13 | UP-PR1 | Lw-R9 | ∘ | ∘ |
| Example B14 | UP-PR2 | Lw-R10 | ∘ | ∘ |
| Example B15 | UP-PR3 | Lw-R11 | ∘ | ∘ |
| Comparative | UP-PR1 | Lw-R12 | x | x |
| Example B1 | | | | |
| Comparative | UP-PR2 | Lw-R13 | x | x |
| Example B2 | | | | |
| Comparative | UP-PR1 | Lw-R14 | x | x |
| Example B3 | | | | |
| Comparative | UP-PR1 | Lw-R15 | x | Δ |
| Example B4 | | | | |
| Comparative | UP-PR1 | Lw-R16 | x | x |
| Example B5 | | | | |
| Comparative | UP-PR1 | LW-R17 | x | Δ |
| Example B6 | | | | |
| Comparative | UP-PR2 | Lw-R18 | x | x |
| Example B7 | | | | |
| Comparative | UP-PR2 | Lw-R19 | x | x |
| Example B8 | | | | |
| Comparative | UP-PR1 | Lw-R20 | x | x |
| Example B9 | | | | |
| Comparative | UP-PR1 | Lw-R21 | x | x |
| Example B10 | | | | |

### <Preparation of Photosensitizer-Containing Under Layer Organic Film Composition>

### EXAMPLES A12 TO A23 AND COMPARATIVE EXAMPLES A11 TO A13

After 100 parts by weight of the novolak resin (a-1), 16 parts by weight of naphthoquinonediazide compound photosensitizer (b-1), and 280 parts by weight of propylene glycol monomethyl ether acetate were mixed to obtain a uniform solution, the solution was filtered by a microfilter with a hole diameter of 0.2 μm to prepare a photosensitizer-containing under layer organic film composition (hereinafter, referred to also as under layer resist composition) (LW-PR1).

In the same manner, under layer resist compositions (LW-PR2) to (LW-PR12) and (LW-PR13) to (LW-PR15) were prepared by mixing the components in the following compositions (part by weight) as shown in Table 5.

The abbreviations in Table 5 are as follows.

PMA: propylene glycol monomethyl ether acetate
EEP: 3-ethoxyethyl propionate
EL: ethyl lactate
MAK: 2-heptanone

TABLE 5

| | Under layer | Novolak resin | | Photosensitizer | | Solvent | |
|---|---|---|---|---|---|---|---|
| | resist | | Addition | | Addition | | Addition |
| | composition | Type | amount | Type | amount | Type | amount |
| Example A12 | Lw-PR1 | a-1 | 100 | b-1 | 16.0 | PMA | 280 |
| Example A13 | Lw-PR2 | a-2 | 100 | b-1 | 16.0 | PMA | 280 |
| Example A14 | Lw-PR3 | a-3 | 100 | b-1 | 16.0 | PMA | 280 |
| Example A15 | Lw-PR4 | a-1 | 100 | b-1 | 16.0 | PMA | 140 |
| | | | | | | EEP | 140 |
| Example A16 | Lw-PR5 | a-1 | 100 | b-1 | 16.0 | EL | 280 |
| Example A17 | Lw-PR6 | a-1 | 100 | b-1 | 16.0 | EEP | 280 |
| Example A18 | Lw-PR7 | a-1 | 100 | b-1 | 16.0 | MAK | 280 |
| Example A19 | Lw-PR8 | a-1 | 100 | b-1 | 16.0 | Cyclohexanone | 280 |
| Example A20 | Lw-PR9 | a-1 | 100 | b-2 | 16.0 | PMA | 280 |
| Example A21 | Lw-PR10 | a-15 | 100 | b-1 | 16.0 | PMA | 280 |
| Example A22 | Lw-PR11 | a-15 | 96 | b-1 | 16.0 | PMA | 280 |
| | | a-12 | 4 | | | | |
| Example A23 | Lw-PR12 | a-4 | 100 | b-1 | 16.0 | PMA | 280 |
| Comparative | Lw-PR13 | a-5 | 100 | b-1 | 16.0 | PMA | 280 |
| Example A11 | | | | | | | |
| Comparative | Lw-PR14 | a-6 | 100 | b-1 | 16.0 | PMA | 280 |
| Example A12 | | | | | | | |
| Comparative | Lw-PR15 | a-7 | 100 | b-2 | 16.0 | PMA | 280 |
| Example A13 | | | | | | | |

### EXAMPLES B16 TO B31 AND COMPARATIVE EXAMPLES B11 TO B14

The under layer resist composition (LW-PR1) was applied to a silicon substrate with a diameter of 125 mm by a spinner and dried at 120° C. for 120 seconds with a hot plate to form an under layer film with a thickness of 4.0 μm. The positive-tone resist composition for an upper layer (UP-PR1) was applied to the substrate coated with the under layer film by a spinner and dried at 120° C. for 120 seconds with a hot plate to form an upper layer film with a thickness of 3 μm.

### <Bilayer Resist Pattern Formation Evaluation (2)>

The thickness of the resist film at the center (G) of the substrate and the thickness of the resist film at any optional point (J) 2 cm from the edge of the substrate were measured by an optical film thickness measurement instrument. The results (G and J) of the thickness measurement of the resist film before exposure were evaluated based on the following standard.

L=(G/J)×100

◯: 90≦L≦100 (free from intermixing or an intermixing layer was so extremely thin as compared with the bilayer resist film thickness that the layer could be negligible in terms of the profile).
x: 0<L<90 (there was an intermixing layer and the profile was determined to be considerably different in the plane of the substrate and the upper layer resist dropping trace was observable with eyes).

After being subjected to exposure using an i-ray stepper (LD5010i, manufactured by Hitachi, Ltd.), the substrate was subjected to development with an aqueous solution containing 2.38% of tetramethylammonium hydroxide at 23° C. for 150 seconds by DIP method and rinsed with ultrapure water for 20 seconds and dried. The line and space resist pattern with line width of 5 μm in the center part (M) of the thus obtained silicon substrate and the line and space resist pattern at any optional point (P) 2 cm from the edge of the substrate were observed by a scanning electron microscope.

The cross-sectional profile was evaluated based on the following standard.

◯: Both of M and P had a profile having the same cross-section of the pattern.
Δ: Although the both cross-sectional profiles at M and P points were undercut profiles, the profiles were not same.
x: Intermixing was significant, and no undercut profile was observed at M point.

The positive resist compositions for an upper layer (UP-PR2) to (UP-PR9) and under layer resist compositions (Lw-PR2) to (Lw-PR15) were used and evaluation was carried out in the same manner. The results are shown in Table 6.

TABLE 6

| | | | Evaluation | |
|---|---|---|---|---|
| | Upper | Under | result of film | |
| | layer | layer | thickness | Cross-sectional |
| | resist | resist | measurement (L) | profile |
| Example B16 | UP-PR1 | Lw-PR1 | ∘ | ∘ |
| Example B17 | UP-PR2 | Lw-PR2 | ∘ | ∘ |
| Example B18 | UP-PR3 | Lw-PR3 | ∘ | ∘ |
| Example B19 | UP-PR4 | Lw-PR2 | ∘ | ∘ |
| Example B20 | UP-PR1 | Lw-PR4 | ∘ | ∘ |
| Example B21 | UP-PR3 | Lw-PR4 | ∘ | ∘ |
| Example B22 | UP-PR6 | Lw-PR6 | ∘ | ∘ |
| Example B23 | UP-PR7 | Lw-PR7 | ∘ | ∘ |
| Example B24 | UP-PR8 | Lw-PR8 | ∘ | ∘ |
| Example B25 | UP-PR9 | Lw-PR4 | ∘ | ∘ |
| Example B26 | UP-PR9 | Lw-PR2 | ∘ | ∘ |
| Example B27 | UP-PR1 | Lw-PR9 | ∘ | ∘ |
| Example B28 | UP-PR2 | Lw-PR10 | ∘ | ∘ |
| Example B29 | UP-PR3 | Lw-PR11 | ∘ | ∘ |
| Example B30 | UP-PR5 | Lw-PR5 | ∘ | ∘ |
| Example B31 | UP-PR4 | Lw-PR12 | ∘ | ∘ |
| Comparative | UP-PR1 | Lw-PR13 | x | x |
| Example B11 | | | | |
| Comparative | UP-PR2 | Lw-PR14 | x | x |
| Example B12 | | | | |
| Comparative | UP-PR1 | Lw-PR15 | x | Δ |
| Example B13 | | | | |
| Comparative | UP-PR1 | Lw-PR14 | x | x |
| Example B14 | | | | |

### INDUSTRIAL APPLICABILITY

The invention makes it possible to carry out multilayer resist process easily using conventional facilities for a monolayer resist process with no need of a facility capable of dealing with baking at a high temperature in fabrication process of semiconductor integrated circuits and light emitting devices and the invention is thus remarkably advantageous for an electronic device production method.

1. An organic film composition for an under layer organic film for forming a resist pattern with an undercut profile on a substrate by carrying out exposure through a mask and development of a bilayer organic film composed of the under layer organic film and an upper layer positive photoresist film formed on the substrate, wherein the composition comprises (A) an alkali-soluble resin obtained by condensation of (A1) a phenol component which is a mixture of 3-methylphenol and 4-methylphenol and (A2) an aldehyde component comprising an aromatic aldehyde and formaldehyde, and (B) a solvent.

2. The organic film composition according to claim 1, wherein the solvent (B) is the solvent same as that contained in the composition for forming the upper layer positive photoresist film.

3. The organic film composition according to claim 2, wherein the solvent (B) is a glycol ether ester.

4. The organic film composition according to claim 1, wherein the alkali-soluble resin (A) has a weight average molecular weight in a range from 4000 to 14000 on the basis of polystyrene standards.

5. The organic film composition according to claim 1, wherein the organic film composition is a radiation-sensitive composition comprising a naphthoquinonediazide compound.

6. The organic film composition according to claim 5, wherein the naphthoquinonediazide compound is a compound defined by the following formula (I): 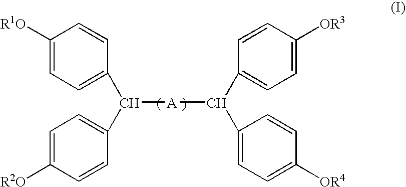
wherein R¹, R², R³, and R⁴ may be same or different and independently denote a hydrogen atom or a group defined by the following formula and at least one of R¹, R², R³, and R⁴ is a group defined by the following formula: 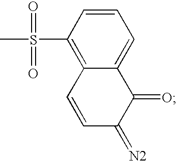
and A denotes a phenylene group, an optionally branched C₁ to C₁₂ alkylene group, an optionally substituted arylene group, or a heteroarylene group.

7. A method for forming a resist pattern comprising steps of applying the organic film composition according to claim 1 to a substrate; baking the composition at a temperature equal to or lower than 130° C. for forming an under layer film; applying the positive type photoresist composition to the under layer film and baking the photoresist composition for forming an upper layer positive type photoresist film; and carrying out exposure through a mask and development for forming a resist pattern having an undercut profile on the substrate.

8. The organic film composition according to claim 2, wherein the alkali-soluble resin (A) has a weight average molecular weight in a range from 4000 to 14000 on the basis of polystyrene standards.

9. The organic film composition according to claim 3, wherein the alkali-soluble resin (A) has a weight average molecular weight in a range from 4000 to 14000 on the basis of polystyrene standards.

10. The organic film composition according to claim 2, wherein the organic film composition is a radiation-sensitive composition comprising a naphthoquinonediazide compound.

11. The organic film composition according to claim 3, wherein the organic film composition is a radiation-sensitive composition comprising a naphthoquinonediazide compound.

12. The organic film composition according to claim 4, wherein the organic film composition is a radiation-sensitive composition comprising a naphthoquinonediazide compound.

13. The organic film composition according to claim 8, wherein the organic film composition is a radiation-sensitive composition comprising a naphthoquinonediazide compound.

14. The organic film composition according to claim 9, wherein the organic film composition is a radiation-sensitive composition comprising a naphthoquinonediazide compound.

15. The organic film composition according to claim 10, wherein the naphthoquinonediazide compound is a compound defined by the following formula (I): 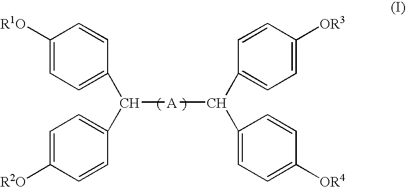
wherein R¹, R², R³, and R⁴ may be same or different and independently denote a hydrogen atom or a group defined by the following formula and at least one of R¹, R², R³, and R⁴ is a group defined by the following formula: 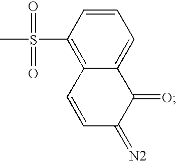
and A denotes a phenylene group, an optionally branched C₁ to C₁₂ alkylene group, an optionally substituted arylene group, or a heteroarylene group.

16. The organic film composition according to claim 11, wherein the naphthoquinonediazide compound is a compound defined by the following formula (I): 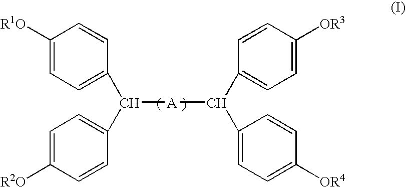
wherein R¹, R², R³, and R⁴ may be same or different and independently denote a hydrogen atom or a group defined by the following formula and at least one of R¹, R², R³, and R⁴ is a group defined by the following formula: 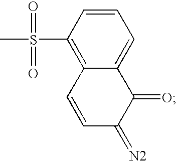
and a denotes a phenylene group, an optionally branched C₁ to C₁₂ alkylene group, an optionally substituted arylene group, or a heteroarylene group.

17. The organic film composition according to claim 12, wherein the naphthoquinonediazide compound is a compound defined by the following formula (I): 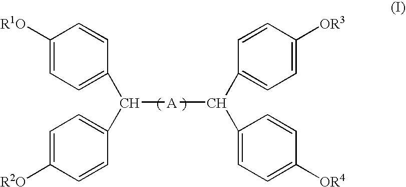
wherein R¹, R², R³, and R⁴ may be same or different and independently denote a hydrogen atom or a group defined by the following formula and at least one of R¹, R², R³, and R⁴ is a group defined by the following formula: 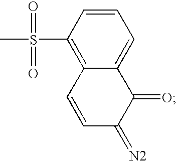
and A denotes a phenylene group, an optionally branched C₁ to C₁₂ alkylene group, an optionally substituted arylene group, or a heteroarylene group.

18. The organic film composition according to claim 13, wherein the naphthoquinonediazide compound is a compound defined by the following formula (I): 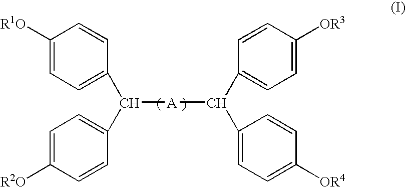
wherein R¹, R², R³, and R⁴ may be same or different and independently denote a hydrogen atom or a group defined by the following formula and at least one of R¹, R², R³, and R⁴ is a group defined by the following formula: 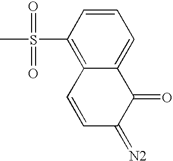
and A denotes a phenylene group, an optionally branched C₁ to C₁₂ alkylene group, an optionally substituted arylene group, or a heteroarylene group.

19. The organic film composition according to claim 14, wherein the naphthoquinonediazide compound is a compound defined by the following formula (I): 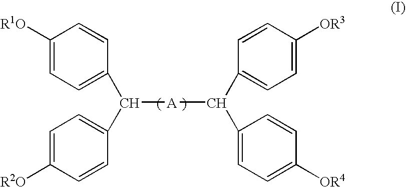
wherein R¹, R², R³, and R⁴ may be same or different and independently denote a hydrogen atom or a group defined by the following formula and at least one of R¹, R², R³, and R⁴ is a group defined by the following formula: 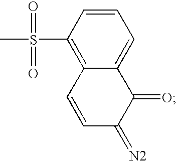
and A denotes a phenylene group, an optionally branched C₁ to C₁₂ alkylene group, an optionally substituted arylene group, or a heteroarylene group.
